(19) United States
(12) Patent Application Publication
(10) Pub. No.: US 2007/0257759 A1
(43) Pub. Date: Nov. 8, 2007

(54) Noise filter and manufacturing method thereof

(75) Inventors: Cheng-Hong Lee, Taoyuan Hsien (TW); Yu-Lin Hsueh, Taoyuan Hsien (TW); Yi-Hong Huang, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/826,483

(22) Filed: Jul. 16, 2007

Related U.S. Application Data
(63) Continuation-in-part of application No. 11/266,302, filed on Nov. 4, 2005.

(30) Foreign Application Priority Data
Jul. 17, 2006 (TW) 95126099
Jul. 28, 2006 (TW) 95127659

(51) Int. Cl. H01F 27/33; H01F 27/02

(52) U.S. Cl. 336/90; 29/602.1

(57) ABSTRACT

A noise filter and a manufacturing method thereof are provided. The noise filter includes a common mode choke having a core to eliminate common mode noise, and a magnetic body enclosing and covering the common choke to eliminate differential mode noise. The core and the magnetic body have different initial permeability (μᵢ).

This Non-provisional application is a CIP of U.S. Ser. No. 11/266,302 filed on Nov. 4, 2005, which claims priority under U.S.C. §119(a) on Patent Application No(s). 200410101951.4 filed in China on Dec. 15, 2004, Patent Application No. 095126099 filed in Taiwan R.O.C. on Jul. 17, 2006 and Patent Application No. 095127659 filed in Taiwan R.O.C. on Jul. 28, 2006, the entire contents of which are hereby incorporated by reference.

### BACKGROUND

The invention relates to a noise filter, and in particular to a noise filter capable of simultaneously eliminating both common mode noise and differential mode noise.

Electronic devices are currently in widespread use. Most electronic devices are driven by electrical power. A common type of electrical power is referred to as alternating current (AC). Alternating current typically generates noise due to a power supply, high-frequency transformer, or operation of the parasitic capacitance and stray capacitance of other components in the device, commonly referred to as electrical interference.

Generally, noise generated when using alternating current includes differential mode noise and common mode noise. EMI filters can serve as the first line of defense against electromagnetic radiation. An EMI filter is mainly comprised of a choke coil and a capacitor. The choke coil restrains noise generation or prevents noise from entering the electrical devices or electrical apparatuses. FIG. 1A shows a core 1a of a conventional choke coil. In FIG. 1A, the core 1a of a choke coil consists of a thin coiled strip of an amorphous alloy, and has at least one cut air gap 2a. Because the amorphous alloy has disadvantages like operating frequency being less than 100 kHz, and low resistance to DC-bias, thus the cut air gap 2a is formed in the core 1a in order to modify the resistance to DC-bias. The initial permeability (μᵢ) of the choke coil is, however, greatly reduced.

FIGS. 1B and 1C are schematic views of another two conventional choke coils. As shown in FIG. 1B, three individual magnetic cores 11a, 11b and 11c are integrated to form a choke coil 11 in order to eliminate common mode noise. The cores 11a, 11b and 11c are comprised of an oxide magnetic substance, and an insulating or viscous material is applied between and separates each core. Because the cores 11a, 11b and 11c are comprised of a highly permeable oxide magnetic substance, the choke coil 11 can has large impedance in the low frequency band (10 kHz side). The permeability in the high frequency band (10 MHz side) is also high due to dimensional resonance, thus, the impedance is large. Three cores joined together, however, tend to increase overall volume of the choke coil, hindering miniaturization. Further, this type of choke coil eliminates only common mode noise, not differential mode noise.

As shown in FIG. 1C, the conventional choke coil includes two individual cores, an outer core 111 and an inner core 114, wound together by a coil 18. The outer core 111 is comprised of a material with high magnetic permeability, such as ferrite or an amorphous material, and the inner core 114 is comprised of a material with a relative low magnetic permeability, such as dust core. Also, the cores 111 and 114 are isolated by an insulating material disposed therebetween. The high permeability of the outer core 111 may eliminate common mode noise, while the low permeability of the inner core 114 may eliminate differential mode noise. Nevertheless, the arrangement of the independent cores maximizes the volume of the choke coil, which is adverse to miniaturization. Further, disposing the insulating material between the cores is costly in both material and time.

### SUMMARY

The invention provides miniaturized and cost efficient noise filter capable of efficiently eliminating common mode noise and differential mode noise.

Accordingly, a noise filter and a manufacturing method thereof are provided. An exemplary embodiment of a noise filter includes a common mode choke including a core, at least one coil wound around the core; and a magnetic body enclosing the common choke, wherein the core and the magnetic body have different initial permeability (μi ).

The core includes ferrite, and the magnetic body includes magnetic slurry. The magnetic slurry includes a magnetic filler and resin. The resin is thermosetting resin or photopolymer resin. The magnetic filler includes iron, Fe-based magnetic alloy, magnetic Mn—Zn ferrite powder, or Ni—Zn ferrite. The Fe-based magnetic alloy includes Fe—Si alloy, Fe—Ni alloy, Fe—Si—Al alloy, Mo—Fe—Ni alloy or iron. The magnetic slurry includes the magnetic filler at a weight percentage of more than 10% and less than 98%.

The noise filter further includes an isolative housing enclosing the core, wherein the coil is wound around the core and the isolative housing. In addition, the noise filter further includes a casing in which the common mode choke and the magnetic body are disposed.

Another exemplary embodiment of a noise filter includes a common mode choke including a core to eliminate common mode noise; a magnetic body enclosing and covering the common choke to eliminate differential mode noise; and at least one coil wound around the magnetic body, wherein the core and the magnetic body have different initial permeability (μ).

The magnetic body has a smaller initial permeability than the core. The magnetic body is formed by injection molding or powder compression molding. The magnetic body includes a sintering-type magnetic material or a magnetic plastic material. The sintering-type magnetic material is sintering-type Mn—Zn ferrite, sintering-type Ni—Zn ferrite, or sintering-type magnetic iron alloy. The magnetic plastic material includes a curing magnetic powder and a thermoset polymer. The curing magnetic powder includes curing Mn—Zn ferrite, curing Ni—Zn ferrite, curing magnetic iron alloy, or a curing non-crystallized material with iron. The magnetic plastic material further includes a coupling material to perform a surface processing for the curing magnetic powder.

The magnetic body includes an upper housing and a lower housing, and the common mode choke is disposed in a space formed by assembling the upper housing and the lower housing.

The noise filter further includes an isolative casing enclosing the magnetic housing, wherein the coil is wound around the isolative casing.

### DESCRIPTION OF THE DRAWINGS

The invention can be more fully understood by reading the subsequent detailed description and examples with references made to the accompanying drawings, wherein:

FIG. 1A is a schematic view of a core of a conventional choke coil;

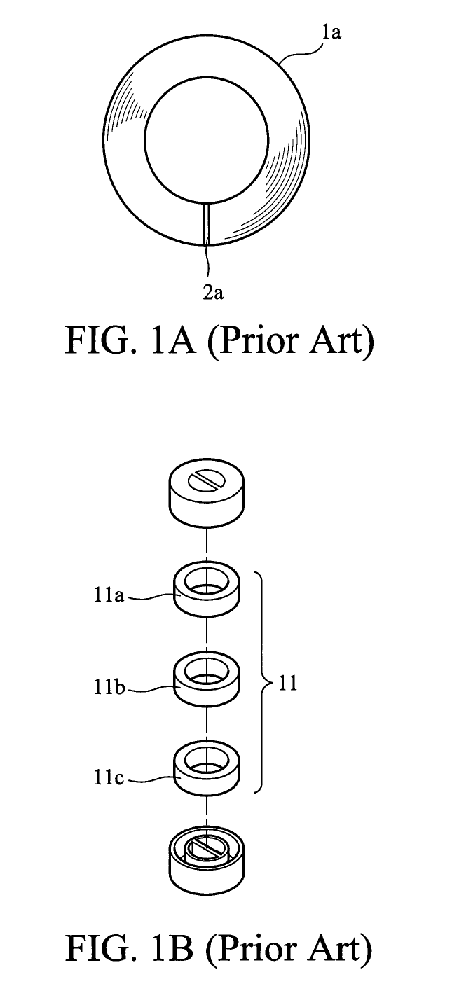

FIGS. 1B and 1C are schematic views of another two conventional choke coils;

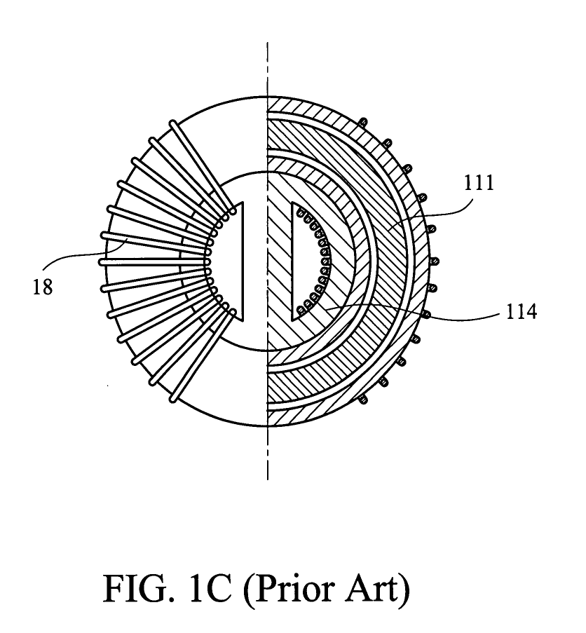

FIGS. 2A to 2C depict a manufacturing method of the noise filter according to the preferred embodiment of the present invention;

FIG. 3 is a schematic view of the common mode choke of the noise filter in FIG. 2C;

FIGS. 4A and 4B are schematic views of another noise filter according to the preferred embodiment of the present invention;

FIG. 4C a schematic view showing the interior of the noise filter in FIG. 4B without coils;

FIG. 4D is a cross-sectional view along line B-B′ in FIG. 4C;

FIG. 5 depicts another magnetic body and the common mode choke according to the preferred embodiment of the present invention;

FIG. 6 depicts the noise filter having the magnetic body and the common mode choke in FIG. 5;

FIG. 7 shows the noise measurement of a conventional choke coil; and

FIG. 8 shows the noise measurement of the noise filter of the embodiment of the present invention.

### DETAILED DESCRIPTION

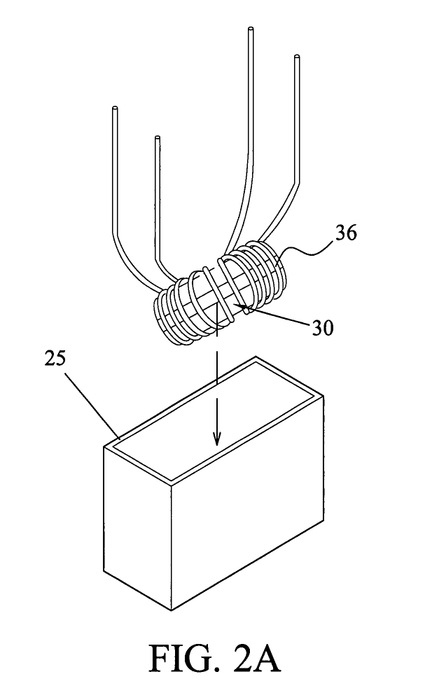

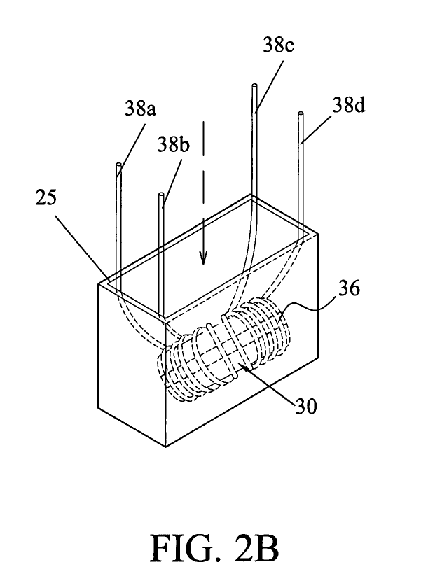

The invention provides a noise filter and a manufacturing method thereof. Referring to FIGS. 2A, 2B, 2C and 3, FIGS. 2A to 2C depict a manufacturing method of the noise filter according to the preferred embodiment of the present invention, and FIG. 3 is a schematic view of the common mode choke of the noise filter in FIG. 2C. In FIG. 2C, the noise filter 2 includes a common mode choke 30, a magnetic body 22 and a casing 25.

Referring both FIG. 2C and FIG. 3, the common mode choke 30 includes a core 32 and two coils 36. The core 32 is formed by injection molding or by powder compression molding.

The core 32 is made of ferrite, and the magnetic body 22 is made of magnetic slurry including magnetic filler and a resin. The magnetic slurry includes the magnetic filler at a weight percentage of more than 10% and less than 98%.

The resin can be thermosetting resin or photopolymer resin. The magnetic filler includes a magnetic powder of iron, Fe-based magnetic alloy, Mn—Zn ferrite or Ni—Zn ferrite. The Fe-based magnetic alloy includes Fe—Si alloy, Fe—Ni alloy, Fe—Si—Al alloy, Mo—Fe—Ni alloy or iron.

Further, the common mode choke 30 has an isolative housing 34 which encloses the core 32 so as to enhance the insulation and prevent the core 32 from contacting the magnetic body 22.

The two coils 36 are wound around the core 32 and the isolative housing 34 and have four leads 38a, 38b, 38c and 38d. The magnetic body 22 is formed by injection and curing. The magnetic body 22 encloses the common mode choke 30. The common mode choke 30 and the magnetic body 22 are disposed in the casing 25.

The manufacturing method of the noise filter 2 is described in detail as below. The manufacturing method includes the following steps:

A casing 25 is provided, and the common mode choke 30 with the wound coils 36 is provided, as shown in FIG. 2A. As shown in FIG. 2B, the common mode choke 30 is placed into the casing 25 which has a space corresponding to the magnetic body 22. Next, the casing 25 is filled with a magnetic slurry and then a curing procedure is performed. After the curing procedure, the magnetic body 22 is formed and encloses the common mode choke 30, and the noise filter 2 is accomplished. Only the four leads 38a′, 38b′, 38c′ and 38d′ protrude from the magnetic body 22 for connection, as shown in FIG. 2C.

Referring to FIG. 2C and FIG. 3 again, the core 32 and the magnetic body 22 have different initial permeability (μ). As the magnetic body 22 has a lower permeability than the core 32, the magnetic body 22 eliminates differential mode noise, and the core 32 eliminates common mode noise. In such a structure, the noise filter 2 can eliminate differential mode noise and common mode noise simultaneously. Additionally, as the common mode choke 30 is embedded in the magnetic body 22, the volume of the filter noise 2 is reduced.

When the magnetic body 22 is included of the composite magnetic material, the magnetic body 22 has a lower magnetic permeability than the core 32 for filtering differential mode noise while the magnetic body 22 is included of ferrite has a high magnetic permeability for filtering common mode noise. Thus, only the single choke coil is capable of eliminating both common mode and differential mode noise, at reduced costs and volume.

Further, the material of the magnetic body 22 can be substituted with the material of the core 32, such that the magnetic body 22 includes ferrite and the core 32 are included of a composite magnetic material. In other words, the magnetic permeability of the magnetic body 22 can exceed that of the core 32. In this case, the magnetic body 22 filters common mode noise while the core 32 filters differential mode noise.

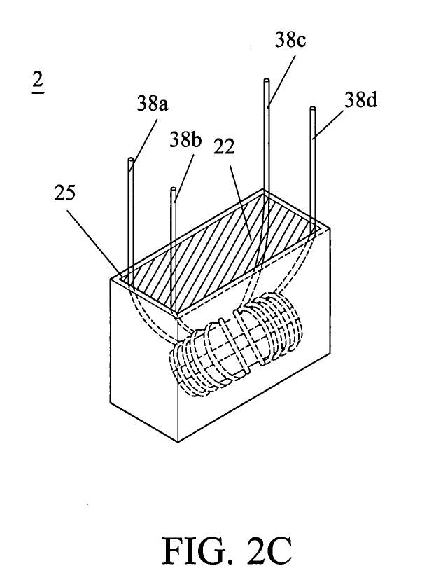

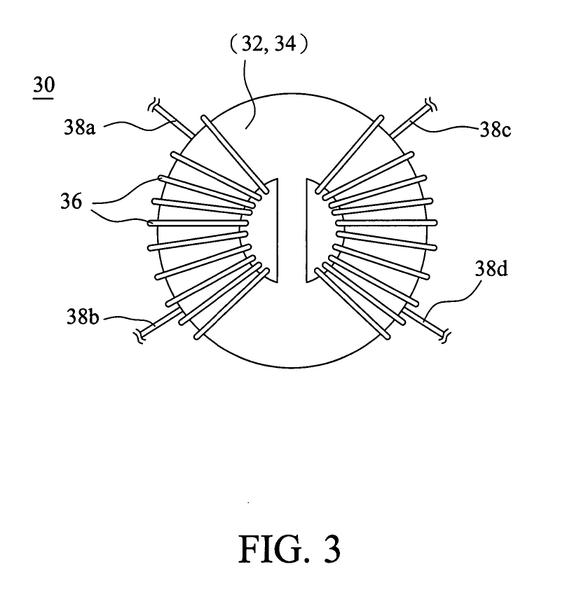

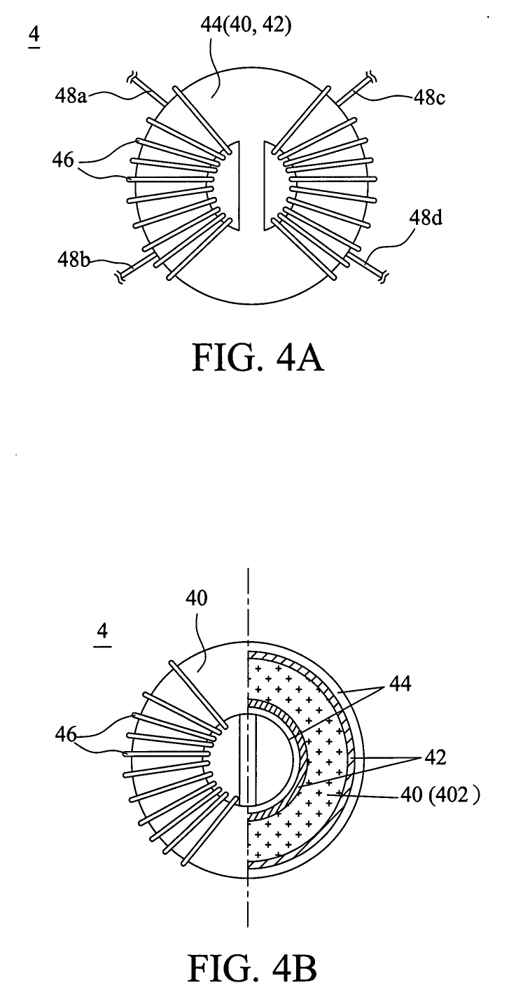

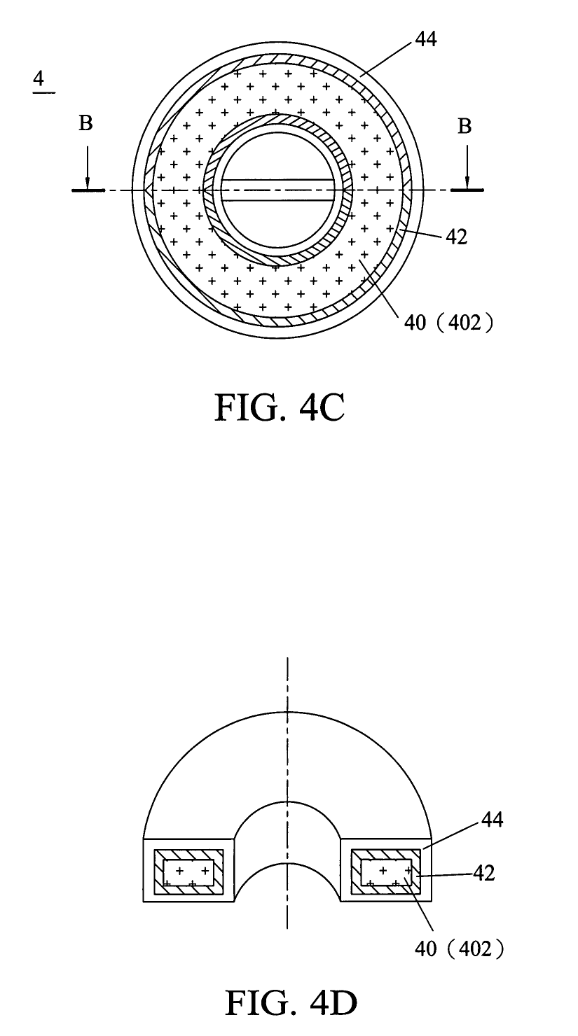

Another embodiment of the noise filter is shown in FIGS. 4A, 4B, 4C and 4D. FIGS. 4A and 4B are schematic views of another noise filter according to the preferred embodiment of the present invention, FIG. 4C a schematic view showing the interior of the noise filter in FIG. 4B without coils, and FIG. 4D is a cross-sectional view along line B-B′ in FIG. 4C. A noise filter 4 includes a common mode choke 40, a magnetic body(magnetic housing) 42 and at least one coil 46. The common mode choke 40 includes a core 402, and the core 402 is made of magnetic ferrite and is formed by injection molding or powder molding. The common mode choke 40 serves to eliminate common mode noise. The magnetic body 42 enclosing the common mode choke 40 serves to eliminate differential mode noise. The magnetic body 42 is formed by injection molding or powder molding. The magnetic body 42 can be either an integral structure or an assembly of an upper housing 52a and a lower hosing 52b as shown in FIG. 5. In FIG. 5, the common mode choke 50 is disposed in a space formed by assembling the upper housing 52a and the lower hosing 52b.

Returning to FIGS. 4A to 4D, the noise filter 4 further includes an isolative casing 44 enclosing the magnetic body 42 to improve insulation and prevent shorts. In this embodiment, two coils 46 are wound around the isolative casing 44, the magnetic body 42, and the common mode choke 40, and the two coils 46 have four leads 48a, 48b, 48c and 48d′. In other words, the common mode choke 40 is embedded in the magnetic body 42, and the isolative casing 44 encloses and covers the magnetic body 42 following with the coils wound around the isolative casing 44.

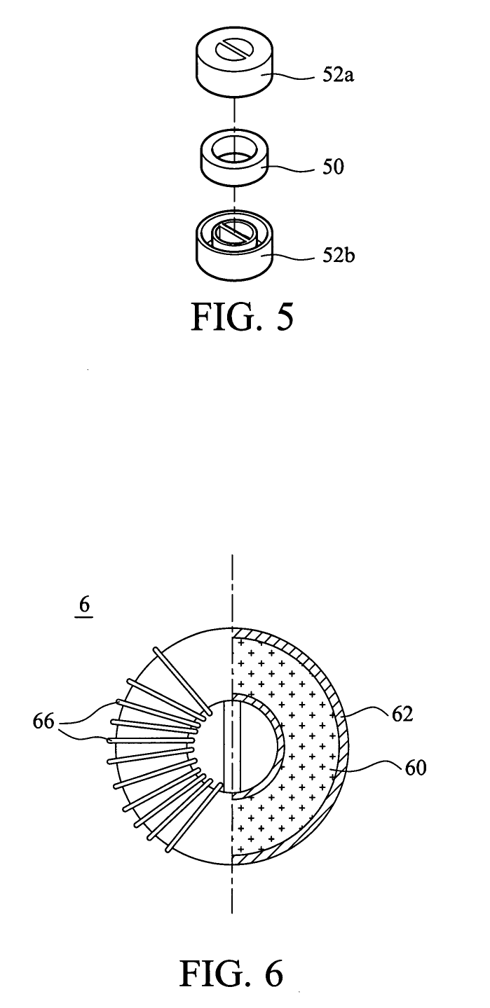

The isolative casing 44 is formed by injection molding or coating an isolative material on the magnetic body 42. The isolative material includes plastic, epoxy or varnish. In another embodiment, the isolative casing 44 is eliminated, as shown in FIG. 6. The coils 46 are wound around the magnetic body 42. The embodiment shown in FIG. 6 can also eliminate common mode noise and differential mode noise.

The material of the magnetic body 42 is a sintering-type magnetic material or a magnetic plastic material. The sintering-type magnetic material is sintering-type Mn—Zn ferrite, sintering-type Ni—Zn ferrite, or sintering-type magnetic iron alloy. The magnetic plastic material is made by mixing a curing magnetic powder and a thermoset polymer. The curing magnetic powder is curing Mn—Zn ferrite, curing Ni—Zn ferrite, curing magnetic iron alloy, or a curing non-crystallized material with iron.

Further, a coupling material can be added into the magnetic plastic material in order to perform a surface processing for the magnetic powder for improvement of the mixing and interface strength of the magnetic powder and the thermoset polymer. The coupling material is silane or titanium.

The core 402 and the magnetic body 42 have different initial permeability. The permeability of the magnetic body 42 is lower than that of the core 402. The magnetic body 42 is employed to eliminate differential mode noise. The core 402 is employed to eliminate common mode noise. In such a structure, the noise filter 4 eliminates common mode noise and differential mode noise simultaneously. As the common mode choke 40 is enclosed by the magnetic body 42, the magnetic leakage is prevented and the volume is reduced.

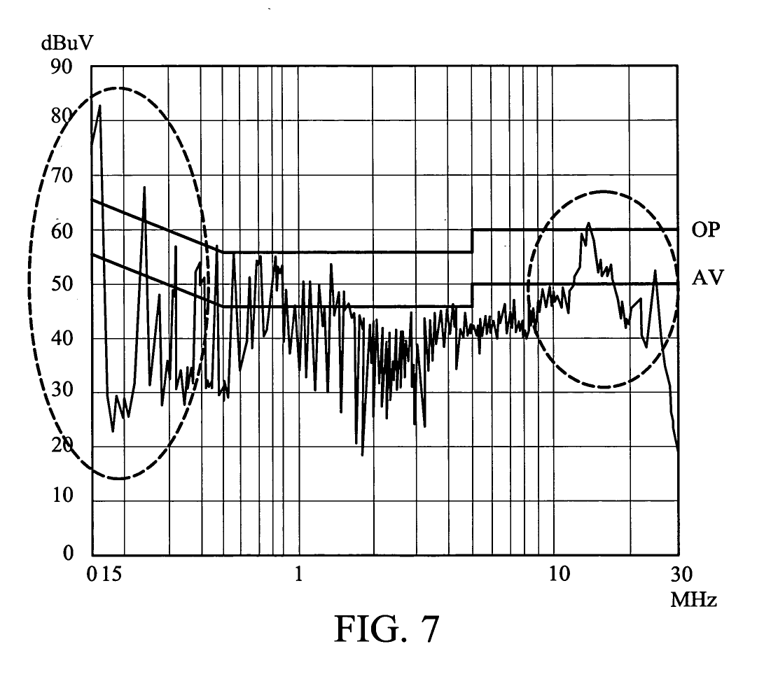

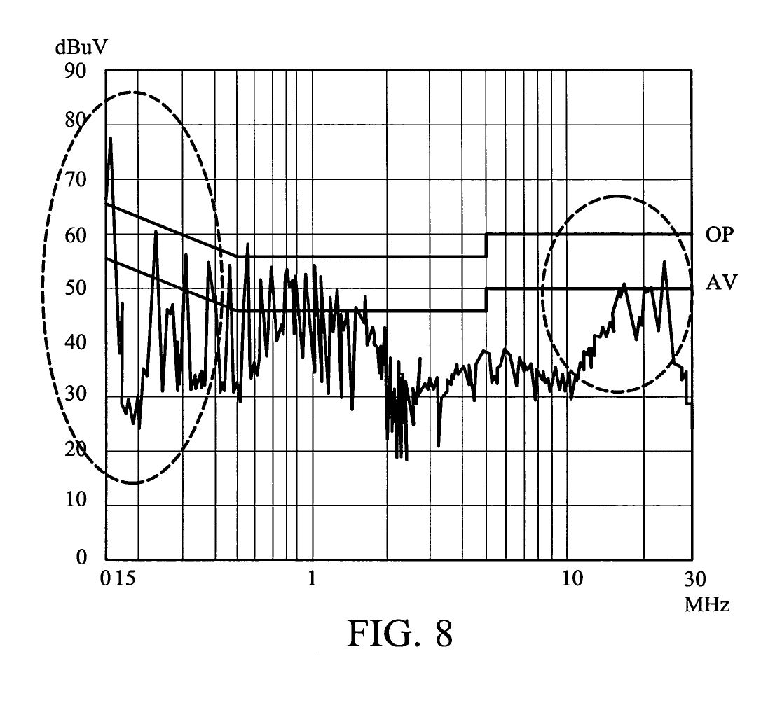

FIG. 7 shows the noise measurement of a conventional choke coil. FIG. 8 shows the noise measurement of the noise filter of the embodiment. The magnetic housing includes Mn—Zn ferrite of 80% weight percentage. Compared with FIGS. 7 and 8, the noise filter of the embodiment suppresses 17 db more than the conventional choke coil at 150 kHz, and 6 db more than the conventional choke coil at 300 kHz. At 1-8 MHz, the measurements of the noise filter of the invention and the conventional choke coil is similar. At 10-30 MHz, the measurements of the noise filter of the invention and the conventional choke coil are different.

In summary, because the core and the magnetic body have different initial permeability (μᵢ), the noise filter and the manufacturing method thereof of the prevent invention are capable of efficiently eliminating common mode noise and differential mode noise simultaneously. Also, noise filter and the manufacturing method thereof of the prevent invention have advantages of small size and cost saving.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A noise filter, comprising:
a common mode choke comprising a core to eliminate common mode noise; and
a magnetic body enclosing and covering the common choke to eliminate differential mode noise, wherein the core and the magnetic body have different initial permeability (μᵢ).

2. The noise filter as claimed in claim 1, wherein the common mode choke further comprises at least one coil wound around the core, and the magnetic body encloses and covers both the core and the at least one coil.

3. The noise filter as claimed in claim 2, further comprising an isolative housing enclosing the core, wherein the at least one coil is wound around the core and the isolative housing.

4. The noise filter as claimed in claim 2, further comprising a casing in which the common mode choke and the magnetic body are disposed.

5. The noise filter as claimed in claim 2, wherein the core comprises ferrite, and the magnetic body comprises a magnetic slurry having a magnetic filler and a resin.

6. The noise filter as claimed in claim 5, wherein the resin is a thermosetting resin or a photopolymer, and the magnetic filler comprises a magnetic powder of iron, Fe-based magnetic alloy, Mn—Zn ferrite or Ni—Zn ferrite.

7. The noise filter as claimed in claim 6, wherein the Fe-based magnetic alloy comprises Fe—Si alloy, Fe—Ni alloy, Fe—Si—Al alloy, Mo—Fe—Ni alloy or iron.

8. The noise filter as claimed in claim 5, wherein the magnetic slurry comprises the magnetic filler at a weight percentage of more than 10% and less than 98%.

9. The noise filter as claimed in claim 1, further comprising at least one coil, wherein the magnetic body encloses and covers the common mode choke, and the at least one coil is wound around both the common mode choke and the magnetic body.

10. The noise filter as claimed in claim 9, wherein the magnetic body has a smaller initial permeability than the core, and the core comprises ferrite and the core is formed by injection molding or powder compression molding.

11. The noise filter as claimed in claim 9, wherein the magnetic body comprises a sintering-type magnetic material or a magnetic plastic material, and the magnetic body is formed by injection molding or powder compression molding.

12. The noise filter as claimed in claim 11, wherein the sintering-type magnetic material comprises sintering-type Mn—Zn ferrite, sintering-type Ni—Zn ferrite, or sintering-type magnetic iron alloy, and the magnetic plastic material comprises a curing magnetic powder and a thermoset polymer.

13. The noise filter as claimed in claim 12, wherein the curing magnetic powder comprises curing Mn—Zn ferrite, curing Ni—Zn ferrite, curing magnetic iron alloy, or a curing non-crystallized material with iron, or the magnetic plastic material further comprises a coupling material to perform a surface processing for the curing magnetic powder, and the coupling material comprises silane or titanium.

14. The noise filter as claimed in claim 9, wherein the magnetic body comprises an upper housing and a lower housing, and the common mode choke is disposed in a space formed by assembling the upper housing and the lower housing.

15. The noise filter as claimed in claim 9, further comprising an isolative casing enclosing the magnetic body, wherein the at least one coil is wound around the isolative casing, the common mode choke and the magnetic body.

16. The noise filter as claimed in claim 15, wherein the isolative casing is formed by injecting or coating an isolative material on the magnetic housing, and the isolative material comprises plastic, epoxy or varnish.

17. A manufacturing method of a noise filter, comprising steps of:
providing a common mode choke comprising a core;
placing the common mode choke in a casing;
filling the casing with a magnetic slurry; and
performing a curing procedure, wherein the magnetic slurry is cured to form a magnetic body enclosing the common mode choke, and the core and the magnetic body have different initial permeability (μ).

18. The manufacturing method as claimed in claim 17, wherein the common mode choke further comprises at least one coil wound around the core, and the magnetic body encloses and covers both the core and the at least one coil.

19. The manufacturing method as claimed in claim 18, further comprising a step of:
forming an isolative housing enclosing the core, wherein the at least one coil is wound around the core and the isolative housing.

20. The manufacturing method as claimed in claim 17, wherein the core is formed by injection molding or by powder compression molding, and the magnetic body is formed by injecting and curing the magnetic slurry.
